(19) United States
(12) Patent Application Publication
(10) Pub. No.: US 2025/0028258 A1
(43) Pub. Date: Jan. 23, 2025

(54) COMPENSATING OPTICAL SYSTEM FOR NONUNIFORM SURFACES, A METROLOGY SYSTEM, LITHOGRAPHIC APPARATUS, AND METHODS THEREOF

(71) Applicant: ASML Netherlands B.V., Veldhoven (NL)

(72) Inventors: Oleg Viacheslavovich VOZNYI, Eindhoven (NL); Haico Victor KOK, Veldhoven (NL)

(73) Assignee: ASML Netherlands B.V., Veldhoven (NL)

(21) Appl. No.: 18/684,391

(22) PCT Filed: Jul. 25, 2022
(86) PCT No.: PCT/EP2022/070832

§ 371 Date: Feb. 16, 2024

Related U.S. Application Data
(60) Provisional application No. 63/235,305, filed on Aug. 20, 2021.

(51) Int. Cl. G03F 9/00; G03F 7/00

(52) U.S. Cl. CPC G03F 9/7034; G03F 7/70633; G03F 9/7084; G03F 9/7088

(57) ABSTRACT

A system includes a radiation source, an optical system, an optical element, a detection system, and a processor. The radiation source is configured to generate a radiation beam. The optical system is configured to direct the radiation beam toward a target structure and to receive the scattered radiation. The target structure is configured to produce scattered radiation comprising one or more scattered beams. The optical element is configured to control a position of the one or more scattered beams. The detection system is configured to receive a portion of the position-controlled scattered radiation and to generate a detection signal. The processor is configured to determine a property of the target structure based on at least the detection signal.

### CROSS-REFERENCE TO RELATED APPLICATIONS

This application claims priority of U.S. Provisional Patent Application No. 63/235,305, which was filed on Aug. 20, 2021, and which is incorporated herein in its entirety by reference.

### FIELD

The present disclosure relates to methods and systems for compensating of a top layer thickness surface tilt, for example, in an alignment sensor.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, it is desirable to frequently make measurements of position of marks on the substrate in order to place device features accurately on the substrate. For example, a lithographic apparatus may use an alignment apparatus for detecting positions of the alignment marks and for aligning the substrate using the alignment marks to ensure accurate exposure from a mask.

### SUMMARY

There is a need to provide improved alignment techniques for alignment mark having a layer with a surface tilt on the top of the alignment mark.

In some embodiments, a method includes irradiating a target structure with a radiation beam, controlling respective positions of one or more scattered beams, receiving a portion of the position-controlled scattered radiation at a detector, generating a detection signal based on the received scattered radiation, and determining a property of the target structure based on at least the detection signal. The target structure can reflect, refract, diffract, scatter, or the like, radiation. For ease of discussion, and without limitation, radiation that interacts with a target will be termed scattered radiation throughout.

In some embodiments, a system includes a radiation source, an optical system, an optical element, a detection system, and a processor. The radiation source is configured to generate a radiation beam. The optical system is configured to direct the radiation beam toward a target structure and to receive the scattered radiation. The target structure is configured to produce scattered radiation comprising one or more scattered beams. The optical element is configured to control a position of the one or more scattered beams. The detection system is configured to receive a portion of the position-controlled scattered radiation and to generate a detection signal. The processor is configured to determine a property of the target structure based on at least the detection signal.

In some embodiments, a lithography apparatus comprises an illumination apparatus, a projection system, and a metrology system. The illumination apparatus is configured to illuminate a pattern of a patterning device. The projection system is configured to project an image of the pattern onto a substrate. The metrology system includes a radiation source, an optical system, an optical element, a detection system, and a processor. The radiation source is configured to generate a radiation beam. The optical system is configured to direct the radiation beam toward a target structure and to receive the scattered radiation. The target structure is configured to produce scattered radiation comprising one or more scattered beams. The optical element is configured to control a position of the one or more scattered beams. The detection system is configured to receive a portion of the position-controlled scattered radiation and to generate a detection signal. The processor is configured to determine a property of the target structure based on at least the detection signal.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIGS. 4A-4B show a schematic of an inspection apparatus, according to some embodiments.

FIG. 5 shows a schematic of exemplary layers on a substrate, according to some embodiments.

FIG. 6A shows a schematic of a system, according to some embodiments.

FIG. 6B shows a side of the system, according to some embodiments.

FIG. 6C shows a top view of the system, according to some embodiments.

FIG. 7 shows a schematic of a system, according to some embodiments.

FIG. 8 shows a schematic that illustrates an operation of a beam position sensor, according to some embodiments.

FIG. 9 shows a process for performing functions related to determining an intensity difference, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc. The term “non-transitory” may be used herein to characterize computer readable media used for storing data, information, instructions, and the like, with the sole exception being a transitory, propagating signal.

Before describing such embodiments in more detail, however, it is instructive to present an example environment in which embodiments of the present disclosure can be implemented.

### Example Lithographic Systems

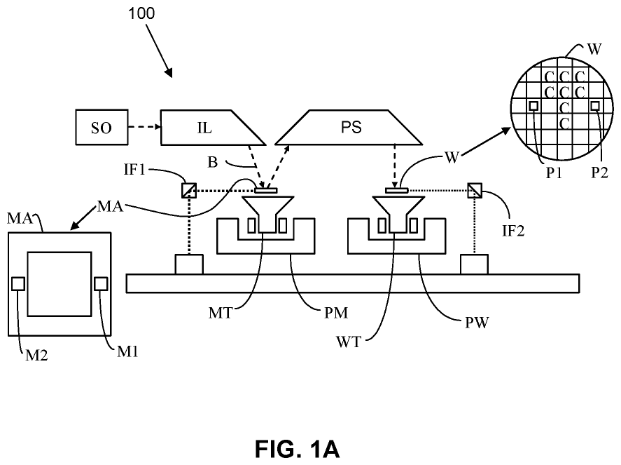

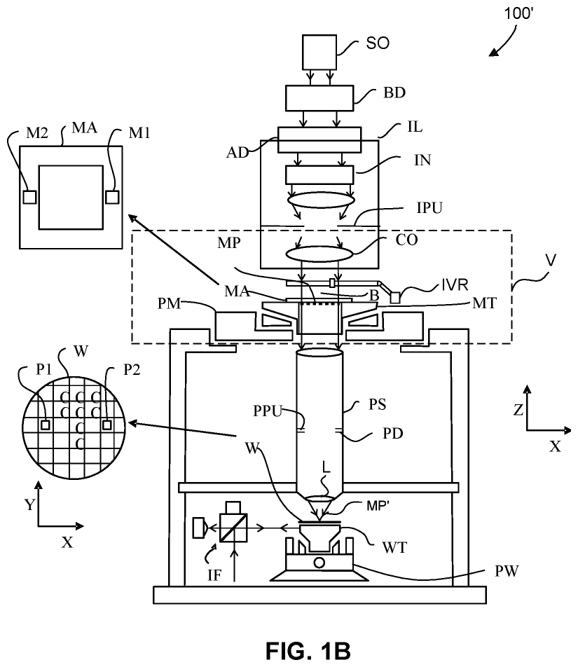

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image MP′ of the mask pattern MP, where image MP′ is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IF (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-) magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In some embodiments, a lithographic apparatus may generate DUV and/or EUV radiation. For example, lithographic apparatus 100′ may be configured to operate using a DUV source. In another example, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

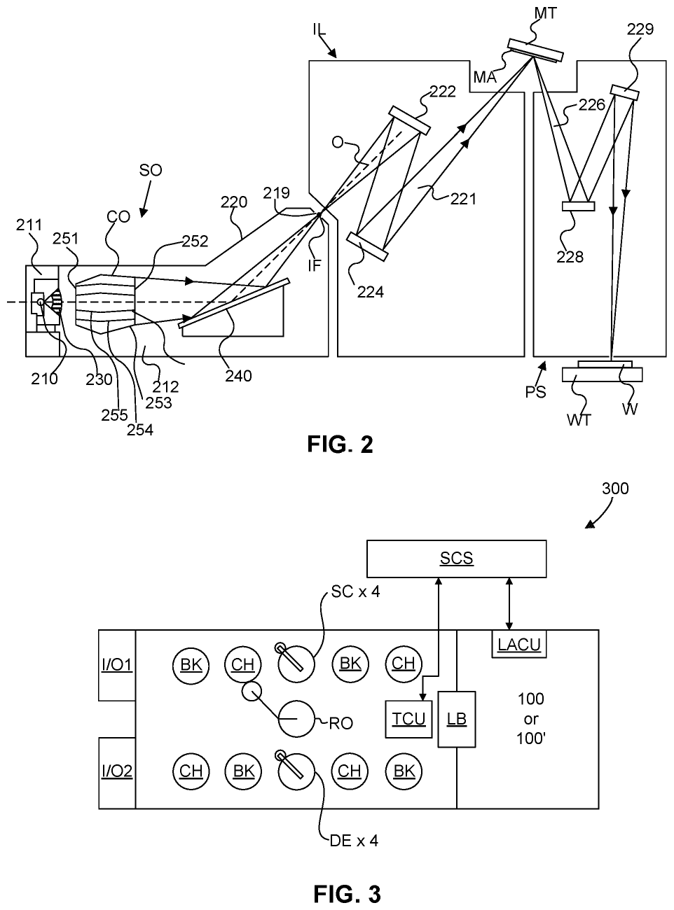

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 can be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point IF. The virtual source point IF is commonly referred to as the intermediate focus, and the source collector apparatus is arranged such that the intermediate focus IF is located at or near an opening 219 in the enclosing structure 220. The virtual source point IF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the radiation beam 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 can optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

FIG. 3 shows a lithographic cell 300, also sometimes referred to a lithocell or cluster, according to some embodiments. Lithographic apparatus 100 or 100′ may form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

### Exemplary Inspection Apparatuses

In order to control the lithographic process to place device features accurately on the substrate, alignment marks are generally provided on the substrate, and the lithographic apparatus includes one or more alignment apparatuses and/or systems by which positions of marks on a substrate must be measured accurately. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.), which is incorporated by reference herein in its entirety. Generally, marks are measured separately to obtain X- and Y-positions. A combined X- and Y-measurement may be performed using the techniques described in U.S. Publication No. 2009/195768 A (Bijnen et al.), which is also incorporated by reference herein in its entirety.

The terms “inspection apparatus,” “metrology apparatus,” and the like may be used herein to refer to, e.g., a device or system used for measuring a property of a structure (e.g., overlay error, critical dimension parameters) or used in a lithographic apparatus to inspect an alignment of a wafer (e.g., alignment apparatus).

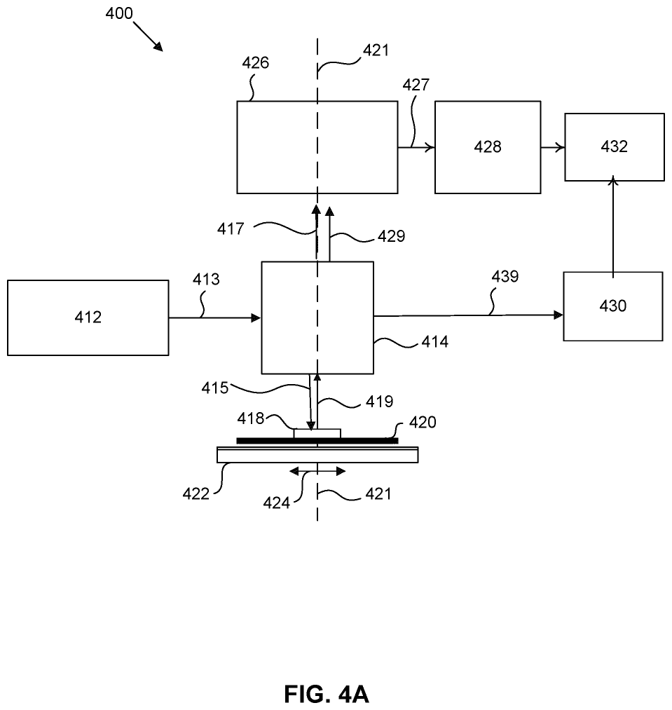

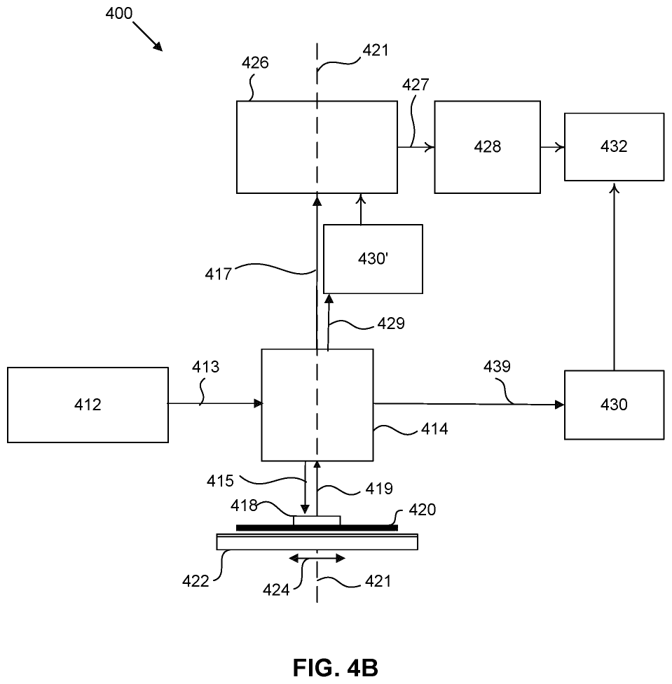

FIG. 4A shows a schematic of a cross-sectional view of an inspection apparatus 400 that can be implemented as a part of lithographic apparatus 100 or 100′, according to some embodiments. In some embodiments, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

In some embodiments, inspection apparatus 400 can include an illumination system 412, a beam splitter 414, an interferometer 426, a detector 428, a beam analyzer 430, and an overlay calculation processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection apparatus 400) compared to the current alignment apparatuses.

In some embodiments, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some embodiments, alignment mark or target 418 can have one hundred and eighty degrees (i.e.,) 180° symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. Where are (a), (b) and (c) shown? The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some embodiments, beam splitter 414 can be further configured to receive diffraction radiation beam 419 and split diffraction radiation beam 419 into at least two radiation sub-beams, according to an embodiment. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example embodiment, diffracted radiation sub-beam 429 can be at least a portion of radiation sub-beam 415 that can be reflected from alignment mark or target 418. In an example of this embodiment, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed, but that the features of alignment mark 418 should be resolved. Interferometer 426 can be further configured to rotate one of the two images with respect to the other of the two images 180° and recombine the rotated and unrotated images interferometrically.

In some embodiments, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference can be due to alignment mark or target 418 being 180° symmetrical, and the recombined image interfering constructively or destructively, according to an example embodiment. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further embodiment, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can be obtained, for example, with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some embodiments, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some embodiments, beam analyzer 430 can be directly integrated into inspection apparatus 400, or connected via fiber optics of several types: polarization preserving single mode, multimode, or imaging, according to other embodiments.

In some embodiments, beam analyzer 430 can be further configured to determine the overlay data between two patterns on substrate 420. One of these patterns can be a reference pattern on a reference layer. The other pattern can be an exposed pattern on an exposed layer. The reference layer can be an etched layer already present on substrate 420. The reference layer can be generated by a reference pattern exposed on the substrate by lithographic apparatus 100 and/or 100′. The exposed layer can be a resist layer exposed adjacent to the reference layer. The exposed layer can be generated by an exposure pattern exposed on substrate 420 by lithographic apparatus 100 or 100′. The exposed pattern on substrate 420 can correspond to a movement of substrate 420 by stage 422. In some embodiments, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some embodiments, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some embodiments, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each typically requires a separate pre-amplifier. The number of elements is therefore limited. CCD linear arrays offer many elements that can be read-out at high speed and are especially of interest if phase-stepping detection is used.

In some embodiments, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform at least all the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some embodiments, second beam analyzer 430′ can be directly integrated into inspection apparatus 400, or it can be connected via fiber optics of several types: polarization preserving single mode, multimode, or imaging, according to other embodiments. Alternatively, second beam analyzer 430′ and beam analyzer 430 can be combined to form a single analyzer (not shown) configured to receive and determine the optical states of both diffracted radiation sub-beams 429 and 439.

In some embodiments, processor 432 receives information from detector 428 and beam analyzer 430. For example, processor 432 can be an overlay calculation processor. The information can comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection apparatus 400 with reference to wafer marks and/or alignment marks 418.

In some embodiments, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm can be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error can be deduced. By way of example and not limitation, Table 1 illustrates how this can be performed. The smallest measured overlay in the example shown is −1 nm. However, this is in relation to a target with a programmed overlay of −30 nm. Consequently, the process must have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value can be taken to be the reference point and, relative to this, the offset can be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 can also be obtained from marks and target 418 under different illumination settings, the illumination setting, which results in the smallest overlay error, and its corresponding calibration factor, can be determined and selected. Following this, processor 432 can group marks into sets of similar overlay error. The criteria for grouping marks can be adjusted based on different process controls, for example, different error tolerances for different processes.

In some embodiments, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the inspection apparatus 400.

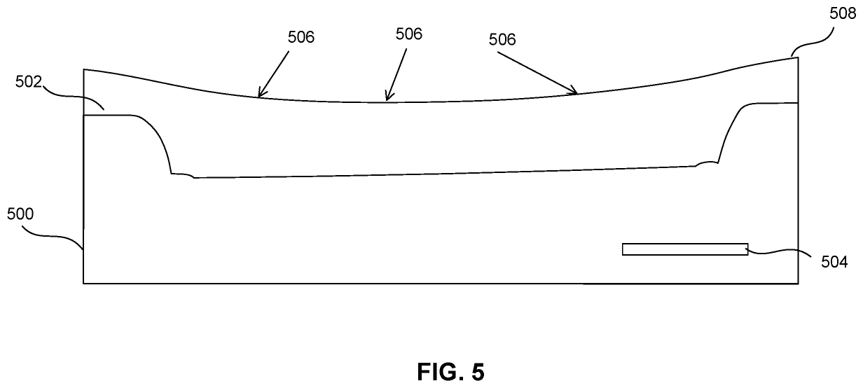

FIG. 5 shows a schematic of an alignment mark 504 on a substrate 500, according to some embodiments. Evolution of thick stacks (e.g., 3D-NAND technology) has increased height differences over substrate 500. In addition, a thickness of a resist layer 502 has increased. Thus, the layers on the surface of the substrate 500 can no longer be considered to be ‘thin and flat’. In some aspects, the thickness of resist layer 502 can be from 10 μm to 20 μm that is non-identical to a topology of the 3D NAND layers. In some aspects, top surface 508 of resist layer 502 can be tilted by several degrees (shown by arrows 506 in FIG. 5). This typically happens in the scribelanes, where the alignment marks are located (e.g., alignment mark 504). In some aspects, a scribelane may form a deep trench on the surface of the substrate 500. The resist does not fill the trench uniformly when the substrate 500 is covered with resist. As a result, alignment mark 504 can be located under an area with a tilted resist surface as shown in FIG. 5. In this situation, measurement of the positions of alignment marks may be inaccurate. For example, an alignment sensor (e.g., inspection apparatus 400) may completely loose its signal as described further below.

In some embodiments, an illumination beam (e.g., radiation beam 413) may be refracted before the illumination beam can illuminate alignment mark 504. A top surface 508 of resist layer 502 may not be parallel to alignment mark 504 but may be tilted. Therefore, due to the incident illumination beam refraction and the diffraction beams reflection and refraction by the top surface 508, a zero order diffraction beam may not be parallel to an optical axis of the alignment Sensor. The diffraction angles of the higher order diffraction beams +1/−1, . . . , +m/−m with respect to the optical axis of the alignment sensor (e.g., inspection apparatus 400) may not be equal.

In some embodiments, the effects caused by the nonuniformity of top surface 508 can introduce the following drawbacks:

In some aspects, a zero order diffraction beam may be shifted with respect to a spot mirror of the alignment sensor. The spot mirror can block the zero order diffraction beam and prevent the zero order diffraction beam from reaching the higher order diffraction beams. However, the shift can be large enough to have a “leakage” of the zero order into higher order diffraction beams channels because the zero order diffraction beam is not fully blocked by the spot mirror. For example, the shift may be larger than the surface area of the spot mirror such as the zero order diffraction beam is no longer incident on the spot mirror and therefore is not blocked. This “leakage” may reduce the alignment signal signal-to-noise ratio and consequently deteriorate the aligned position measurement accuracy.

In some aspects, phase deltas between the higher order diffraction beams (e.g., +1/−1, . . . +m/−m) may be introduced due to non-equal diffraction angles or different optical path lengths of the higher order diffraction beams in each pair +1/−1, . . . +m/−m. The phase delta may introduce an aligned position error proportional to the phase deltas magnitude.

In some aspects, the alignment sensor may lose signal and alignment may not be possible. In some aspects, a tilt of about one degree in resist layer 502 can cause the alignment sensor to lose the signal.

In some embodiments, an alignment sensor such as an Athena sensor (Advanced Technology using High order ENhancement of Alignment), as described in U.S. Pat. No. 6,297,876 incorporated by reference herein in its entirety, may direct each of seven diffraction orders to a dedicated detector. An aperture stop comprising multiple holes may be used to filter the high order diffraction beams before they reach the dedicated detector. The shifted diffraction orders (in the pupil plane) may be blocked by the aperture stop because they are no longer aligned with holes in the pupil aperture stop and therefore are not detected by the dedicated sensor.

In some embodiments, a second type of alignment sensor may employ a self-referencing interferometer with a single detector and four different wavelengths, and extracts the alignment signal in software such as a SMASH (SMart Alignment Sensor Hybrid) sensor, as described in U.S. Pat. No. 6,961,116 incorporated by reference herein in its entirety. The diffraction orders may be shifted in the pupil plane and may no longer be symmetric with respect to the optical axis of the alignment sensor. After duplication of the orders in the self-referencing interferometer, the two copies of the diffraction orders do not overlap spatially and no interference takes place. Thus, the alignment signal may disappear.

In some embodiments, an optical element may be used to shift the diffraction beams to their non-tilted positions. The term non-tilted position may refer to the position of the diffraction orders when the surface layer of the resist is parallel to the alignment mark (e.g., parallel to the optical axis of the alignment sensor). The optical element may be an active optical element that is controlled by a processor (e.g., processor 432) or a controller. The optical element may include one or more optical elements or optical systems as described further below.

In some embodiments, the optical element may be controlled based on measurement data from a zero-order beam position sensor. The sensor may be configured to measure a position of the zero-order diffraction beam. The sensor can output data indicative of the position to a controller of the optical element. Thus, the controller may actuate the optical element based on the output data to adjust the position of the diffraction beams.

In some embodiments, operation of the optical element may be based on pre-determined values for the tilts of the top surface 508. In such a case, the zero-order beam position sensor may be omitted.

In some embodiments, the optical element may be configured to control the position of scattered beams from the substrate. In some aspects, the optical element may be configured to control an illumination beam incident on the substrate. In other embodiments, the optical element may be configured to control the scattered beams after diffraction on the surface of the substrate 500 takes place.

### Compensating System

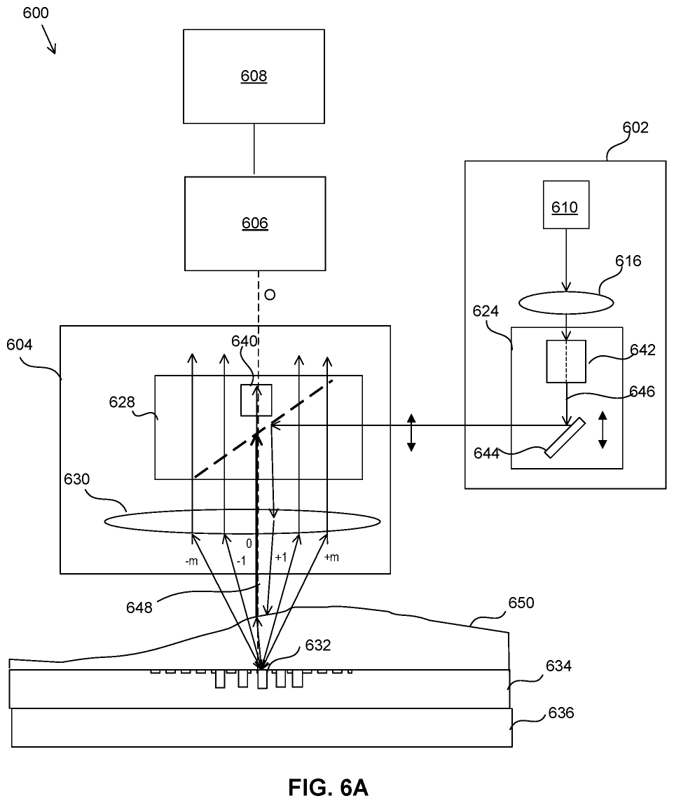

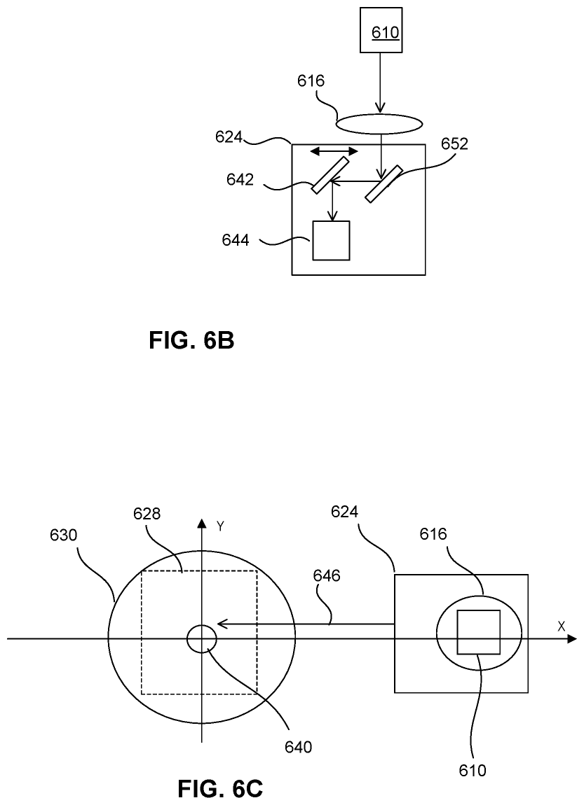

FIG. 6A shows a schematic of a system 600, according to some embodiments. In some embodiments, system 600 can also represent a more detailed view of inspection apparatus 400 (FIGS. 4A and 4B). FIG. 6C shows a top view of the system 600.

In some embodiments, system 600 includes an illumination system 602, an optical system 604, a detector system 606, and a processor 608. Illumination system 602 can comprise a radiation source 610, a first optical element(s) 616 (e.g., a lens or lens system), and an optical element 624. Optical system 604 can comprise a reflective element 628 (e.g., split mirror), an optical element 630 (e.g., an objective lens), and a zero order beam sensor or sensor 640. The detection system 606 can include a self-referencing interferometer and one or more detectors.

FIG. 6A shows a non-limiting depiction of system 600 inspecting a target 632 (also “target structure”) on a substrate 634. The substrate 634 is disposed on a stage 636 that is adjustable (e.g., a support structure that can move). It should be appreciated the structures drawn within illumination system 602 and optical system 604 are not limited to their depicted positions. The positions of structures can vary as necessary, for example, as designed for a modular assembly.

In some embodiments, target 632 can comprise a diffractive structure (e.g., a grating(s)). Target 632 can reflect, refract, diffract, scatter, or the like, radiation. For ease of discussion, and without limitation, radiation that interacts with a target will be termed scattered radiation throughout. The scattered radiation is collected by optical element 630.

In some embodiments, optical element 624 can shift illumination beam 646 in a X and/or Y direction. Optical element 624 can be a reflective system (e.g., mirrors, MEMS (micro-electro-mechanical-systems)).

In some embodiments, optical element 624 can be positioned in the illumination path before optical system 604. In some embodiments, reflective system 624 can include one or more mirrors to adjust a position of illumination beam 646. In some aspects, at each position during the target scan, an angle of the illumination beam 646 can be adjusted along the horizontal X- and Y-axes direction with respect to at top surface of layer 650 (e.g., resist layer). In some embodiments, optical element 624 can adjust a position of illumination beam 646 (incidence angle) such that diffraction beams are shifted to their non-tilted positions. In some embodiments, illumination beam 646 can be shifted by about half the degree tilt in layer 650 (e.g., tilt ±2.5 degrees for 5 degrees resist tilt).

In some embodiments, the beam angle adjustment can be done independently in a vertical plane along the X direction and in a vertical plane along the Y direction. In some aspects, optical element 624 can include a first mirror 642, a second mirror 644, and mirror 652 (shown in FIG. 6B). In some aspects, the adjustment in the X-direction can be done by moving second mirror 644 in the vertical direction. Thus, the incident beam reflection by reflective element 628 is moved in a vertical plane parallel to the X-plane. In some aspects, the angle adjustment in the Y-direction can be done by moving first mirror 642 in the Y-direction. Thus, the incident beam reflection is shifted in a vertical plane parallel to the Y-plane. The shifts in the X- and Y-direction cause an angle of incidence of illumination beam 646 to change with respect to the optical axis (O) of the system 600 and with respect to the top surface of layer 650 since the shifts in the X- and Y-directions are done in the pupil plane of optical element 630.

The angle is adjusted such that the scattered (e.g., reflected) zero order diffraction beam 648 can enter optical element 630 parallel to an optical axis of system 600. In some aspects, optical axis of system 600 can correspond to the optical axis of optical element 630. In some aspects, when the zero order diffraction is parallel to the optical axis, the higher order diffraction beam angles can be equal to each other within each diffraction beam pair (e.g., +1 and −order, +m and −m). Thus, the measure position of target 632 is not dependent on nonuniformity of the top layer 650 and represent the physical real position with respect to the system 600.

In some embodiments, the adjustment of the incident illumination beam 646 can be done based on measurement data from sensor 640. For example, a control loop may be used between sensor 640 and optical element 624. A controller (not shown) may actuate optical element 624 based on the feedback measurement received from sensor 640. For example, controller or processor 608 can determine the respective displacement of first mirror 642 and second mirror 644 based on the position of the zero order diffraction beam 648. In some aspects, sensor 640 can block the zero order diffraction beam 648.

In some embodiments, reflective element 628 (e.g., split mirror) can be partially transmissive. In some aspects, a surface area of reflective element 628 may be such as to enable a range for the incident illumination beam angle adjustment which is sufficient to compensate for the top layer top surface tilt variation effect. In some aspects, reflective element 628 be implemented based on light beam polarization direction separation. For example, incident illumination beam 646 on target or alignment mark 632 (after reflective element 628) can have a first polarization direction. The polarization direction of the diffracted beams may be shifted (e.g., by 90 degree) and be transmitted by reflective element 628.

In some embodiments, sensor 640 can be positioned after the reflective element 628 is the optical path. In some aspects, sensor 640 can measure the zero order diffraction beam position in the XY plane and the beam angle with respect to the optical axis (O) of system 600. In addition, the sensor 640 can block the zero order diffraction beam 648. Thus, the zero order diffraction beam 648 cannot reach detector system 606.

In some embodiments, operation of the optical element may be based on pre-determined values for the tilts. In such a case, sensor 640 can be omitted. In some aspects, alignment mark 632 can be scanned during an alignment setup (calibration) for various positions of illumination beam 646 to determine the position that gives the maximum detection signal at the detector system 606. The settings of optical element 624 corresponding to the position of the illumination beam 646 that gave rise to the maximum detection signal can be used during the alignment scan. For example, the position of first mirror 642 and second mirror 644 may be determined and used during the alignment scan. The alignment setup (calibration) can be repeated for each alignment mark 632.

FIG. 6B is a schematic that shows a side view of illumination system 602, according to some embodiments. First mirror 642 can be moved in the Y-direction. Mirror 652 can reflect illumination beam 646 from radiation source 610 towards first mirror 642.

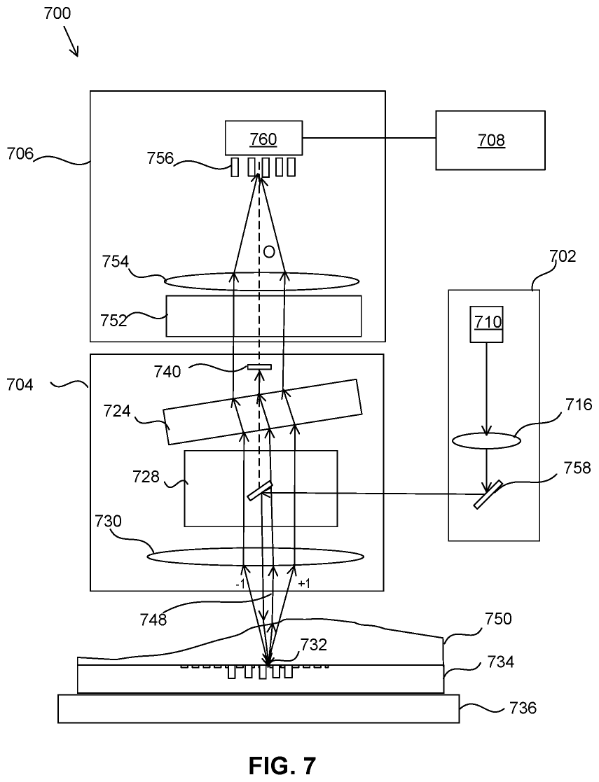

FIG. 7 shows a schematic of a system 700, according to some embodiments. In some embodiments, system 700 can also represent a more detailed view of inspection apparatus 400 (FIGS. 4A and 4B).

In some embodiments, system 700 includes an illumination system 702, an optical system 704, a detector system 706, and a processor 708. Illumination system 702 can comprise a radiation source 710, an optical element(s) 716 (e.g., a lens or lens system), and a mirror 758. Optical system 704 can comprise a reflective element 728 (e.g., spot mirror), an optical element 730 (e.g., an objective lens), and a zero order beam sensor or sensor 740. The detection system 706 can include a self-referencing interferometer 752, optical element 754, and one or more detectors 760. It should be appreciated the structures drawn within illumination system 702, detector system 706, and optical system 704 are not limited to their depicted positions. The positions of structures can vary as necessary, for example, as designed for a modular assembly.

FIG. 7 shows a non-limiting depiction of system 700 inspecting a target 732 (also “target structure”) on a substrate 734. The substrate 734 is disposed on a stage 736 that is adjustable (e.g., a support structure that can move). In some embodiments, target 732 can comprise a diffractive structure (e.g., a grating(s)). Target 732 can reflect, refract, diffract, scatter, or the like, radiation. For ease of discussion, and without limitation, radiation that interacts with a target will be termed scattered radiation throughout. The scattered radiation is collected by optical element 730.

In some embodiments, optical element 724 can be positioned in the detection path. For example, optical element 724 can be positioned in the detection path between reflective element 728 and self-referencing interferometer 752.

In some aspects, optical element 724 can include a planar parallel plate. In some aspects, optical element 724 is configured to be tilted around both the X- and Y-axes. The shift amount may be based on a thickness of the plate and the degree of the tilt of the top surface of layer 750 (e.g., resist layer). In some aspects, the tilt of optical element 724 shifts all the diffraction orders of the diffracted beams in the same directions (e.g., +1, −1, 0). The diffraction beams are shifted to their symmetrical positions with respect to the optical axis O. The tilt of the plate may be based on the thickness of the planar parallel plate, refractive index of the plate, and the tilt in the layer 750. For example, a tilt angle of the plate may be about double the tilt of the top surface of the layer 750 when a thickness of the plate is about 14 mm and have a refractive index of about 1.6.

In some aspects, optical element 724 can be actuated at each position during the target scan to shift the diffracted beams to their non-tilted positions.

In some embodiments, the actuation of optical element 724 (and consequently the shift of the diffracted beam) can be based on measurement data from sensor 740. Reflective element 728 may be semi-transparent to allow a zero order beam 748 to reach the sensor 740. For example, a control loop may be used between sensor 740 and optical element 724. A controller (not shown) may actuate optical element based on the feedback measurement received from sensor 740. For example, the controller or processor 708 can determine a respective tilt in the X and Y directions based on a position of the zero order beam 748. In some aspects, sensor 740 can block the zero order beam 748. Thus, the zero order beam 748 cannot reach the detection system 706.

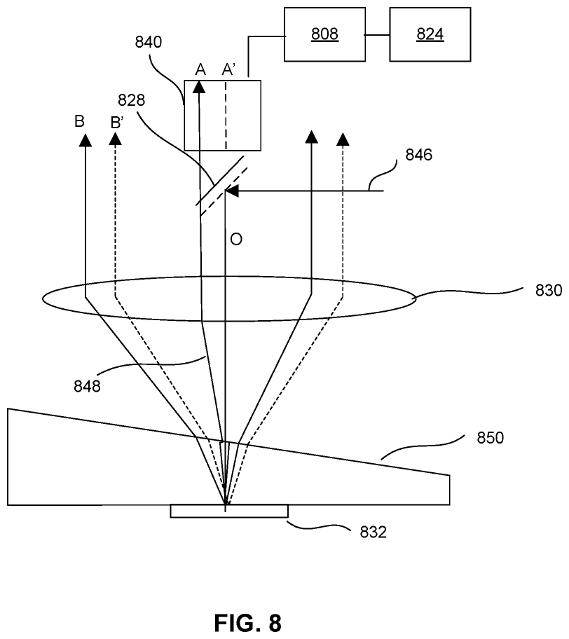

FIG. 8 shows a schematic that illustrates an operation of a beam position sensor 840, according to some embodiments. An illumination beam 846 can illuminate target structure 832. As described previously herein, due to nonuniformity in a top surface of layer 850 (e.g., resist layer), diffracted beams may be shifted with respect to an optical axis (O) of an inspection sensor or alignment sensor. In some embodiments, beam position sensor 840 (e.g., zero order beam sensor 640 of FIG. 6A or zero order beam sensor 740 of FIG. 7) can detect a position of a zero order diffraction beam 848. Zero order diffraction beam 848 can pass through mirror 828 (semi-transparent mirror) to sensor 840. Sensor 840 can measure a difference between the detected position (e.g., position A) and a predetermined position (e.g., position A′). Processor 808 can determine an actuation of optical element 824 (e.g., optical element 624 of FIG. 6A and optical element 724 of FIG. 7) based on the difference. For example, processor 808 can determine the tilt of the optical element 824 (e.g., tilt in the X direction and the Y direction of optical element 724 of FIG. 7). In some embodiments, processor 808 can determine the displacement distance of the mirrors of optical element 824 (e.g., first mirror 642 and second mirror 644 of optical element 624 of FIG. 6).

In some embodiments, illumination beam 846 can be adjusted until the zero order diffraction beam 848 is at position A′ (i.e., is detected by the sensor 840 at position A′ which corresponds to the non-tilted position). In other aspects, the diffracted beams are shifted by the same amount as the difference detected by sensor 840. For example, diffracted beams may be shifted from position B to position B′. Diffracted beams may be shifted using optical element 724 of FIG. 7.

In some embodiments, beam position sensor 840 can be omitted from the inspection system. In such a case, processor 808 can actuate optical element 824 based on calibration data, predetermined recipe values, and the like. In some aspects, the processor 808 can actuate optical element 824 based on a predetermined tilt. The predetermined tilt may be measured in a feed forward modus by a separate tool or an external sensor (e.g., level sensor, ellipsometer, atomic force microscopy, or the like).

In some embodiments, the optical element 824 can be controlled using a full pupil position sensor. In some embodiments, a portion of the scattered beams may be directed to the full pupil position sensor. For example, a beamsplitter positioned between optical element 730 (e.g., objective lens) and self-referencing interferometer 752 may be used to split the light and direct a portion of the light towards the full pupil position sensor. The light is imaged into a camera and pattern recognition may be used to determine the position of all diffraction orders. Then, the processor 808 can actuate optical element 824 based on the measured position of the diffraction orders.

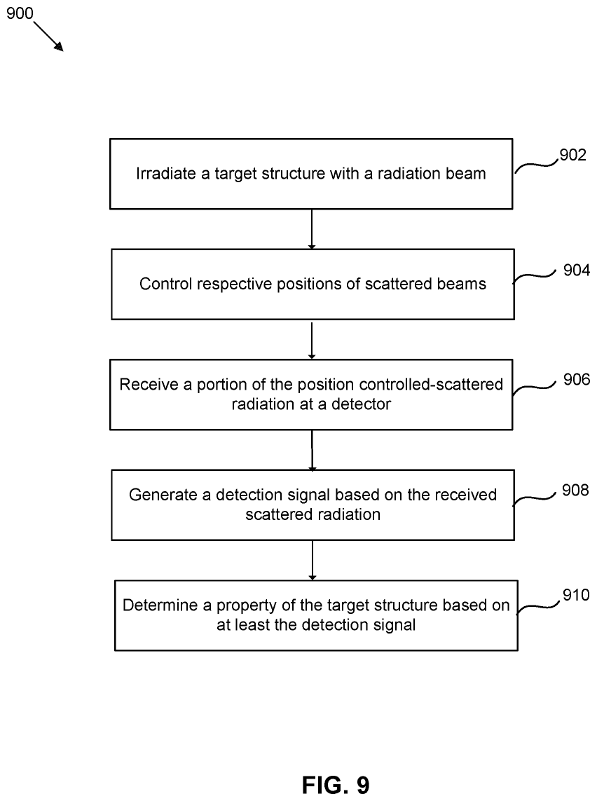

FIG. 9 shows method steps (e.g., using one or more processors) for performing a method 900 including functions described herein, according to some embodiments. The method 900 of FIG. 9 can be performed in any conceivable order and it is not required that all steps be performed. Moreover, the method steps of FIG. 9 described above merely reflect an example of steps and are not limiting.

Method 900 illustrates a method for compensating for top layer thickness surface tilt. Method 900 includes irradiating a target structure with a radiation beam, as illustrated in step 902.

The method also includes controlling respective positions of one or more scattered beams using an optical element, as illustrated in step 904. In some embodiments, the optical element includes a reflective system configured to tilt the radiation beam in a first direction and in a second direction. The first direction may be different from the second direction. In some aspects, the target structure produces scattered radiation that includes the one or more scattered beams. In some aspects, the optical element can independently control the one or more scattered beams.

The method also includes receiving a portion of the position-controlled scattered radiation at a detector, as illustrated in step 906.

The method also includes generating a detection signal based on the received scattered radiation, as illustrated in step 908. The method also includes determining a property of the target structure based on at least the detection signal, as illustrated in step 908.

The embodiments may further be described using the following clauses:
1. A system comprising:
a radiation source configured to generate a radiation beam;
an optical system configured to:
   direct the radiation beam toward a target structure, wherein the target structure is configured to produce scattered radiation from the radiation beam comprising one or more scattered beams, and
   receive the scattered radiation from the target structure;
an optical element configured to control a position of the one or more scattered beams;
a detection system configured to receive a portion of the position-controlled scattered radiation and to generate a detection signal; and
a processor configured to determine a property of the target structure based on at least the detection signal.
2. The system of clause 1, wherein the optical element is positioned in an illumination path between the radiation source and the optical system; and
the optical element is configured to adjust an angle of incidence of the radiation beam with respect to the target structure.
3. The system of clause 2, wherein the optical element comprises a reflective system configured to tilt the radiation beam in a first direction and in a second direction.
4. The system of clause 1, wherein the optical element is positioned in a detection path between the optical system and the detection system; and
   the optical element is configured to shift the one or more scattered beams.
5. The system of clause 4, wherein the optical element comprises a plate configured to be tilted in a first direction and in a second direction.
6. The system of clause 1, further comprising:
   a sensor configured to determine a position of a zero order diffraction beam, wherein the scattered radiation comprises the zero order diffraction beam.
7. The system of clause 6, further comprising:
   a controller configured to control the optical element based on the position of the zero order diffraction beam.
8. The system of clause 6, wherein the sensor is further configured to block the zero order diffraction beam.
9. The system of clause 6, wherein the optical system comprises a split mirror configured to partially transmit the zero order diffraction beam.
10. The system of clause 9, wherein the sensor is positioned in an optical path of the zero order diffraction beam after the split mirror.
11. The system of clause 1, wherein the property of the target structure comprises an alignment position.
12. The system of clause 1, wherein the optical element is configured to independently control a position of the one or more scattered beams.
13. A method comprising:
irradiating a target structure with a radiation beam;
controlling, using an optical element, respective positions of one or more scattered beams, wherein the target structure is configured to produce scattered radiation comprising the one or more scattered beams;
receiving a portion of the position-controlled scattered radiation at a detector;
generating a detection signal based on the received scattered radiation; and
determining a property of the target structure based on at least the detection signal.
14. The method of clause 13, further comprising:
adjusting an angle of incidence of the radiation beam with respect to the target structure.
15. The method of clause 14, wherein the adjusting of the angle of incidence comprises adjusting the angle of incidence in a first direction and in a second direction using a reflective system.
16. The method of clause 13, wherein controlling respective positions of scattered beams comprises shifting the scattered beams in one or more directions.
17. The method of clause 16, wherein the shifting comprises using a plate tiltable in a first direction and in a second direction.
18. The method of clause 13, further comprising:
   determining a position of a zero order diffraction beam of the scattered radiation.
19. The method of clause 18, further comprising:
   controlling the optical element based on the position of the zero order diffraction beam.
20. The method of clause 13, further comprising:
controlling the optical element based on a predetermined tilt of the target structure.
21. The method of clause 20, further comprising:
   receiving the predetermined tilt from an external sensor.
22. The method of clause 13, further comprising:
   determining respective positions of one or more orders of the scattered radiation; and
   controlling the optical element based on the respective positions of the one or more orders of the scattered radiation.
23. A lithography apparatus comprising:
an illumination apparatus configured to illuminate a pattern of a patterning device;
a projection system configured to project an image of the pattern onto a substrate; and
a metrology system including:
a radiation source configured to generate a radiation beam,
an optical system configured to:
   direct the radiation beam toward a target structure, wherein the target structure is configured to produce scattered radiation comprising one or more scattered beams, and
   receive the scattered radiation,
an optical element configured to control a position of the one or more scattered beams,
a detection system configured to receive a portion of the position-controlled scattered radiation and to generate a detection signal, and
a processor configured to determine a property of the target structure based on at least the detection signal.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as synonymous with the more general terms “substrate” or “target portion”, respectively. The substrate referred to herein can be processed, before or after exposure, in for example a track unit (a tool that typically applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The term “substrate” as used herein describes a material onto which material layers are added. In some embodiments, the substrate itself can be patterned and materials added on top of it may also be patterned, or may remain without patterning.

Although specific reference can be made in this text to the use of the apparatus and/or system according to the present disclosure in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific embodiments of the present disclosure have been described above, it will be appreciated that the present disclosure can be practiced otherwise than as described. The description is not intended to limit the present disclosure.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of protected subject matter should not be limited by any of the above-described exemplary embodiments, but should be defined only in accordance with the following claims and their equivalents.

1. A system comprising:
a radiation source configured to generate a radiation beam;
an optical system configured to:
direct the radiation beam toward a target structure, wherein the target structure is configured to produce scattered radiation from the radiation beam comprising one or more scattered beams, and
receive the scattered radiation from the target structure;
an optical element configured to control a position of the one or more scattered beams;
a detection system configured to receive a portion of the position-controlled scattered radiation and to generate a detection signal; and
a processor configured to determine a property of the target structure based on at least the detection signal.

2. The system of claim 1, wherein the optical element is positioned in an illumination path between the radiation source and the optical system; and
the optical element is configured to adjust an angle of incidence of the radiation beam with respect to the target structure.

3. The system of claim 2, wherein the optical element comprises a reflective system configured to tilt the radiation beam in a first direction and in a second direction.

4. The system of claim 1, wherein the optical element is positioned in a detection path between the optical system and the detection system; and
the optical element is configured to shift the one or more scattered beams.

5. The system of claim 4, wherein the optical element comprises a plate configured to be tilted in a first direction and in a second direction.

6. The system of claim 1, further comprising:
a sensor configured to determine a position of a zero order diffraction beam, wherein the scattered radiation comprises the zero order diffraction beam.

7. The system of claim 6, further comprising:
a controller configured to control the optical element based on the position of the zero order diffraction beam.

8. The system of claim 6, wherein the sensor is further configured to block the zero order diffraction beam.

9. The system of claim 6, wherein the optical system comprises a split mirror configured to partially transmit the zero order diffraction beam.

10. The system of claim 9, wherein the sensor is positioned in an optical path of the zero order diffraction beam after the split mirror.

11. The system of claim 1, wherein the property of the target structure comprises an alignment position.

12. The system of claim 1, wherein the optical element is configured to independently control a position of the one or more scattered beams.

13. A method comprising:
irradiating a target structure with a radiation beam;
controlling, using an optical element, respective positions of one or more scattered beams, wherein the target structure is configured to produce scattered radiation comprising the one or more scattered beams;
receiving a portion of the position-controlled scattered radiation at a detector;
generating a detection signal based on the received scattered radiation; and
determining a property of the target structure based on at least the detection signal.

14. The method of claim 13, further comprising:
adjusting an angle of incidence of the radiation beam with respect to the target structure.

15. A lithography apparatus comprising:
an illumination apparatus configured to illuminate a pattern of a patterning device;
a projection system configured to project an image of the pattern onto a substrate; and
a metrology system including:
a radiation source configured to generate a radiation beam,
an optical system configured to:
direct the radiation beam toward a target structure, wherein the target structure is configured to produce scattered radiation comprising one or more scattered beams, and
receive the scattered radiation,
an optical element configured to control a position of the one or more scattered beams,
a detection system configured to receive a portion of the position-controlled scattered radiation and to generate a detection signal, and
a processor configured to determine a property of the target structure based on at least the detection signal.
